(19) United States
(12) Patent Application Publication
(10) Pub. No.: US 2023/0215754 A1
(43) Pub. Date: Jul. 6, 2023

(54) SUBSTRATE PROCESSING APPARATUS AND SUBSTRATE TRANSFER METHOD

(71) Applicant: Tokyo Electron Limited, Minato-ku, Tokyo (JP)

(72) Inventors: Satoru KAWAKAMI, Nirasaki City, Yamanashi (JP); Nobuo MATSUKI, Nirasaki City, Yamanashi (JP)

(21) Appl. No.: 17/996,524

(22) PCT Filed: Apr. 14, 2021
(86) PCT No.: PCT/JP2021/015400

§ 371 Date: Oct. 19, 2022

(30) Foreign Application Priority Data
Apr. 27, 2020 (JP) 2020-078614

(51) Int. Cl. H01L 21/677; H01J 37/32; H01L 21/67; C23C 16/50; C23C 16/455; C23C 16/54; C23C 16/458

(52) U.S. Cl. CPC H01L 21/67754; H01J 37/32733; H01L 21/67161; H01L 21/6719; C23C 16/50; C23C 16/45565; C23C 16/54; C23C 16/4583; H01J 2237/201; H01J 2237/20235; H01J 2237/20214; H01J 2237/3321; H01L 21/68707

(57) ABSTRACT

A substrate processing apparatus includes: a vacuum transfer chamber including a substrate transfer mechanism provided in a vacuum transfer space thereof to collectively hold and transfer substrates with a substrate holder; and a processing chamber having processing spaces and connected to the vacuum transfer chamber. The processing chamber includes a loading/unloading port provided on a side of the vacuum transfer chamber to allow the vacuum transfer space and the processing spaces to communicate with each other. The processing spaces include a first processing space in which a first process is performed on the substrate and a second processing space in which a second process is performed on the substrate subjected to the first process. The first and second processing spaces are arranged in a direction in which the substrate is loaded and unloaded, and the substrate holder has a length that extends over the first and second processing spaces.

### TECHNICAL FIELD

The present disclosure relates to a substrate processing apparatus and a substrate transfer method.

### BACKGROUND

Patent Document 1 discloses a vacuum processing system including a vacuum transfer module, a plurality of vacuum processing apparatuses, a loading/unloading port, and a loading/unloading module. The vacuum transfer module includes a vacuum transfer chamber, and a substrate transfer mechanism disposed in the vacuum transfer chamber and provided with a substrate holder configured to transfer a substrate. The vacuum processing apparatuses perform a vacuum process by supplying a processing gas to a substrate placed in a processing space kept in a vacuum atmosphere. The vacuum processing apparatuses are connected to the vacuum transfer chamber so that the transfer of the substrate is performed between the vacuum transfer chamber and the processing space via the loading/unloading port. A transfer container that accommodates substrates to be processed is placed in the loading/unloading port. The loading/unloading module performs loading/unloading of the substrate between the transfer container and the vacuum transfer module.

### PRIOR ART DOCUMENT

### Patent Document

Patent Document 1: Japanese Laid-Open Patent Publication No. 2019-220509

In a substrate processing apparatus that performs a first process and a second process on a substrate in this order, a technique according to the present disclosure prevents a vacuum transfer space from being adversely affected by a substrate subjected to the first process and further to be subjected to the second process, or to prevent a substrate subjected to the first process and further subjected to the second process from being adversely affected by the atmosphere of the vacuum transfer space.

### SUMMARY

According to an aspect of the present disclosure, a substrate processing apparatus for processing a substrate includes: a vacuum transfer chamber having a vacuum transfer space defined therein while being kept in a vacuum atmosphere, and including a substrate transfer mechanism provided in the vacuum transfer space and configured to collectively hold and transfer a plurality of substrates with a substrate holder; and a processing chamber having a plurality of processing spaces defined therein while being kept in the vacuum atmosphere, and connected to the vacuum transfer chamber, wherein the processing chamber includes a loading/unloading port provided on a side of the vacuum transfer chamber and configured to allow the vacuum transfer space and the plurality of processing spaces to communicate with each other, the plurality of processing spaces include a first processing space in which a first process is performed on the substrate loaded into the first processing space through the loading/unloading port, and a second processing space in which a second process is performed on the substrate subjected to the first process, the first processing space and the second processing space are arranged in a substrate loading/unloading direction in which the substrate is loaded and unloaded via the loading/unloading port by the substrate transfer mechanism, and the substrate holder of the substrate transfer mechanism has a length that extends over the first processing space and the second processing space.

According to the present disclosure, in a substrate processing apparatus that performs a first process and a second process on a substrate in this order, it is possible to prevent a vacuum transfer space from being adversely affected by a substrate subjected to the first process and further to be subjected to the second process, or to prevent a substrate subjected to the first process and further to be subjected to the second process from being adversely affected by the atmosphere of the vacuum transfer space.

### BRIEF DESCRIPTION OF DRAWINGS

FIG. 1 is a plan view schematically illustrating an outline of a configuration of a wafer processing apparatus as a substrate processing apparatus according to a first embodiment.

FIGS. 2A to 2D are views illustrating states of wafer holders in each operation of wafer processing performed by using the wafer processing apparatus according to the first embodiment.

FIGS. 3A and 3B are views illustrating states of the wafer holders in each operation of wafer processing performed by using the wafer processing apparatus according to the first embodiment.

FIGS. 4A and 4B are views illustrating states of the wafer holders in each operation of wafer processing performed by using the wafer processing apparatus according to the first embodiment.

FIGS. 5A to 5C are views illustrating states of wafer holding units in each operation of wafer processing performed by using the wafer processing apparatus according to a second embodiment.

FIGS. 6A and 6B are views illustrating states of the wafer holding units in each operation of wafer processing performed by using the wafer processing apparatus according to the second embodiment.

FIG. 7 is a plan view schematically illustrating an outline of a configuration of a wafer processing apparatus according to a third embodiment.

FIGS. 8A to 8C are views illustrating states of wafer holders in each operation of wafer processing performed by using the wafer processing apparatus according to the third embodiment.

FIGS. 9A and 9B are views illustrating states of the wafer holders in each operation of wafer processing performed by using the wafer processing apparatus according to the third embodiment.

FIGS. 10A to 10C are views illustrating states of the wafer holders in each operation of wafer processing performed by using the wafer processing apparatus according to the third embodiment.

FIGS. 11A to 11C are views illustrating states of wafer holding units in each operation of wafer processing performed by using the wafer processing apparatus according to a fourth embodiment.

FIGS. 12A and 12B are views illustrating states of the wafer holding units in each operation of wafer processing performed by using the wafer processing apparatus according to the fourth embodiment.

### DETAILED DESCRIPTION

In a semiconductor device manufacturing process, for example, various types of processes such as a film forming process on a substrate such as a semiconductor wafer (hereinafter, referred to as a “wafer”) are performed in individual processing spaces under a vacuum atmosphere for respective processes. A number of the above-mentioned film forming processes and the like is performed on one substrate as required. Therefore, there is known a substrate processing apparatus in which in order to improve throughput or the like, a plurality of processing chambers, in which different processes are respectively performed, are connected to each other via a vacuum transfer chamber, which is configured to transfer a substrate therein under a vacuum atmosphere, so that various types of processes are continuously performed without exposing the substrate to the air atmosphere.

However, in such a substrate processing apparatus, a substrate subjected to a first process in a first processing chamber passes through the vacuum transfer chamber when being transferred to the second processing chamber in which a second process subsequent to the first process is to be performed. Therefore, the vacuum transfer space may be adversely affected by the substrate to be subjected to the first process and the second process. Specifically, for example, a component volatilized from a film formed on the surface of the substrate in the first process may adhere to the surface of the inner wall of the vacuum transfer chamber. In addition, a substrate subjected to the first process and further to be subjected to the second process may be adversely affected by the atmosphere in the vacuum transfer space. Specifically, for example, the surface of a substrate subjected to the first process may be oxidized by oxygen in the atmosphere of the vacuum transfer chamber.

Therefore, in a substrate processing apparatus that performs a first process and a second process on a substrate in this order, the technique according to the present disclosure prevents a vacuum transfer space from being adversely affected by a substrate subjected to the first process and further to be subjected to the second process, or to prevent a substrate subjected to the first process and further to be subjected to the second process from being adversely affected by the atmosphere of the vacuum transfer space.

Hereinafter, the configuration of a substrate processing apparatus according to the present embodiment will be described with reference to the drawings. In this specification, elements having substantially the same functional configurations will be denoted by the same reference numerals and redundant descriptions will be omitted.

### First Embodiment

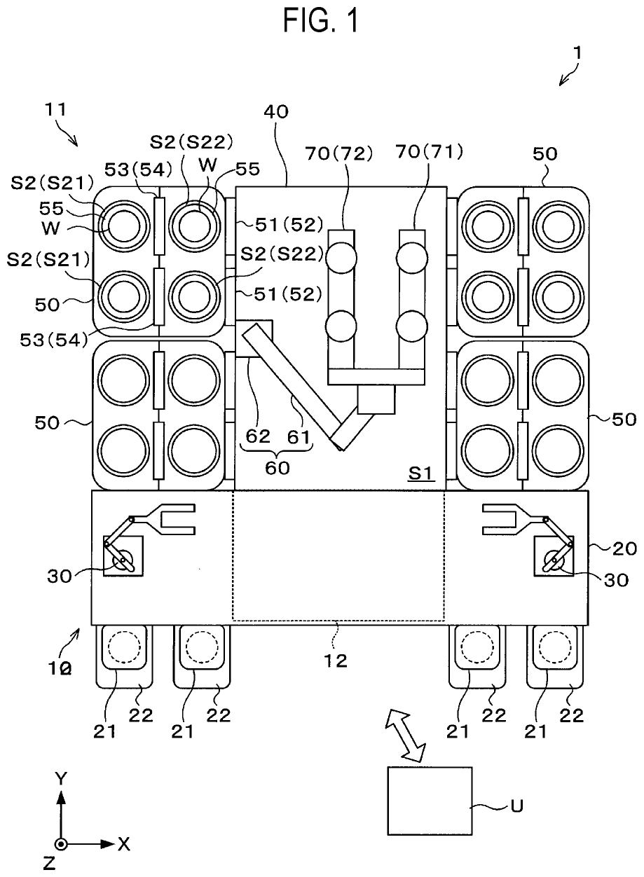

FIG. 1 is a plan view schematically illustrating an outline of a configuration of a wafer processing apparatus as a substrate processing apparatus according to a first embodiment. In the present embodiment, a wafer processing apparatus 1 performs a chemical vapor liquid deposition process as a first process and an annealing process as a second process subsequent to the first process on a wafer W as a substrate. For example, the wafer W is made of silicon and has a pattern having fine recesses formed on a surface thereof.

As illustrated in FIG. 1, the wafer processing apparatus 1 includes an atmospheric section 10 and a decompression section 11, and has a configuration in which the atmospheric section 10 and the decompression section 11 are integrally connected to each other. The atmospheric section 10 includes an atmospheric module configured to perform a desired process on the wafer W under atmospheric pressure. The decompression section 11 includes a decompression module configure to perform a desired process on the wafer W in a decompressed atmosphere.

In this example, the atmospheric section 10 incorporates a load-lock chamber 12. The atmospheric section 10 and the decompression section 11 are connected to each other via the load-lock chamber 12.

The load-lock chamber 12 is configured to temporarily accommodate the wafer W transferred from an atmospheric transfer chamber 20 of the atmospheric section 10, which will be described later, in order to deliver the wafer W to a vacuum transfer chamber 40 of the decompression section 11, which will be described later. In addition, the load-lock chamber 12 is configured to be capable of switching the interior thereof between an atmospheric pressure atmosphere and a decompressed atmosphere.

The load-lock chamber 12 is configured to be capable of accommodating a plurality of wafers W (four in this example). Specifically, the load-lock chamber 12 is provided with a plurality of wafer supports (not illustrated) for supporting the wafers W. In this example, the wafers W are arranged two by two in the front-rear direction (the Y direction in the drawing) and in the widthwise direction (the X direction in the drawing), that is, a total of four wafers W are provided. Further, in the load-lock chamber 12, for example, a plurality of lift pins are provided for delivering the wafers W to and from a wafer transfer mechanism 30 or a wafer transfer mechanism 60, which will be described later.

The load-lock chamber 12 is connected to the atmospheric transfer chamber 20, which will be described later, via a loading/unloading port (not illustrated) provided with a gate valve. The load-lock chamber 12 is connected to a vacuum transfer chamber 40, which will be described later, via a loading/unloading port (not illustrated) provided with a gate valve.

The atmospheric section 10 includes an atmospheric transfer chamber 20 including a wafer transfer mechanism 30, which will be described later, and a load port 22 in which a FOUP 21 is placed. The FOUP 21 is a container that is capable of storing the plurality of wafers W. An orienter module (not illustrated) configured to adjust an orientation of the wafer W in a horizontal direction may be provided adjacent to the atmospheric transfer chamber 20.

The atmospheric transfer chamber 20 includes a rectangular housing in a plan view, and the interior of the housing is kept in an atmospheric pressure atmosphere. On the front side (the negative side in the Y direction in the figure) of the housing of the atmospheric transfer chamber 20, there are a plurality of load ports, for example, two load ports on one side in the widthwise direction (the negative side in the X direction in the figure) and two load ports on the other side in the widthwise direction (the positive side in the X direction in the figure), that is, a total of four load ports 22 are arranged side by side. The vacuum transfer chamber 40 is connected to the center in the widthwise direction (the X direction in the figure) in the surface of the housing of the atmospheric transfer chamber 20 on the rear side (the positive side in the Y direction in the figure).

The above-described load-lock chamber 12 is provided in the center of the interior of the atmospheric transfer chamber 20 in a widthwise direction. Wafer transfer mechanisms 30 configured to transfer the wafers W are provided on one side in the widthwise direction (the negative side in the X direction in the figure) and on the other side in the widthwise direction (the positive side in the X direction in the figure), respectively, inside the atmospheric transfer chamber 20. The wafer transfer mechanisms 30 are configured to transfer the wafers W between the FOUPs 21 in the load ports 22 and the load-lock chamber 12.

The decompression section 11 includes a vacuum transfer chamber 40 and a processing chamber 50. The interiors of the vacuum transfer chamber 40 and the processing chamber 50 are each maintained in a decompressed atmosphere, that is, in a vacuum atmosphere.

The vacuum transfer chamber 40 includes, for example, a rectangular housing in a plan view, and is connected to the load-lock chamber 12 as described above. The vacuum transfer chamber 40 is provided such that the wafer W loaded into the load-lock chamber 12 is transferred to one processing chamber 50, and the wafer W subjected to a chemical vapor liquid film forming process and an annealing process in the one processing chamber 50 is unloaded to the atmospheric section 10 via the load-lock chamber 12.

A wafer transfer mechanism 60 as a substrate transfer mechanism is provided in a space kept in a vacuum atmosphere inside the vacuum transfer chamber 40, that is, a vacuum transfer space S1. The wafer transfer mechanism 60 loads and unloads the wafer W to and from the processing chamber 50 while holding the wafer W.

The wafer transfer mechanism 60 includes a transfer arm 61 constituted with an articulated arm provided, at a tip end thereof, with a wafer holder 70 as a substrate holder configured to hold the wafer W, and a base 62 configured to pivotally support the base portion of the transfer arm 61.

The wafer transfer mechanism 60 includes a pair of wafer holders 70. Hereinafter, one of the wafer holders 70 may be referred to as a first wafer holder 71 and the other may be referred to as a second wafer holder 72.

Each of the first wafer holder 71 and the second wafer holder 72 is formed in an elongated plate shape extending in the horizontal direction. In addition, the first wafer holder 71 and the second wafer holder 72 are provided to be parallel to each other. The first wafer holder 71 has a length that is capable of extending over a first processing space S21 and a second processing space S22 of the processing chamber 50, which will be described later, and is capable of collectively holding a plurality of (two in this example) wafers W aligned in the longitudinal direction (length direction) thereof. The first wafer holder 71 has a width (the length perpendicular to the longitudinal direction in the horizontal plane) that is smaller than, for example, the diameter of the wafer W. The length and width of the second wafer holder 72 are the same as those of the first wafer holder 71.

With the configuration described above, the wafer transfer mechanism 60 is capable of collectively holding and transferring the plurality of wafers W with the wafer holders 70.

In addition, a plurality of processing chambers 50 are connected to the housing of the vacuum transfer chamber 40. For example, two processing chambers 50 are connected to the surface of the housing of the vacuum transfer chamber 40 on one side in the widthwise direction (the negative side in the X direction in the figure) and two chambers are connected to the surface on the other side (the positive side of the X direction in the figure), that is, a total of four processing chambers 50 are connected to the housing.

In addition, the load-lock chamber 12 is connected to the front side of the housing of the vacuum transfer chamber 40 (the negative side in the Y direction in the figure).

Each processing chamber 50 includes a housing having a rectangular shape in a plan view (a square shape in a plan view in the example of the figure), and a plurality of processing spaces S2 are provided inside the housing. A loading/unloading port 51, which allows the vacuum transfer space S1 and the processing space S2 to communicate with each other, is provided on a side of the vacuum transfer chamber 40 of each processing chamber 50. A gate valve 52 is provided in the loading/unloading port 51.

Each of the processing chambers 50 includes, as the processing spaces S2, a first processing space S21 in which a chemical vapor phase liquid film forming process is performed on the wafer W, and a second processing space S22 in which an annealing process is performed on the wafer W on which the chemical vapor liquid film forming process has been performed (hereinafter, referred to as a “wafer W subjected to a chemical vapor liquid film forming process”).

In each processing chamber 50, the first processing space S21 and the second processing space S22 are arranged to be adjacent to each other in a wafer loading/unloading direction (the X direction in the figure) in which the wafer transfer mechanism 60 of the vacuum transfer chamber 40 passes through the loading/unloading port 51. Specifically, in the wafer loading/unloading direction, the first processing space S21 is located on the rear side with reference of the vacuum transfer chamber 40, and the second processing space S22 is located on the front side with reference to the vacuum transfer chamber 40.

In each processing chamber 50, between the first processing space S21 and the second processing space S22, there is provided a loading/unloading port 53 that allows the first processing space S21 and the second processing space S22 to communicate with each other, and the loading/unloading port 53 is provided with a gate valve 54.

In each processing chamber 50, a plurality of (two in the example of the figure) first processing spaces S21 are provided to be arranged in a direction (the Y direction in the figure) orthogonal to the wafer loading/unloading direction in the horizontal plane. This makes it possible to simultaneously perform the chemical vapor liquid film forming process on the plurality of (two in the example illustrated in the figure) wafers in each processing chamber 50.

Similarly, in each processing chamber 50, the second processing spaces S22 are arranged in the same number as the first processing spaces S21 in a direction (the Y direction in the figure) orthogonal to the wafer loading/unloading direction in the horizontal plane. This makes it possible to simultaneously perform the annealing process on the plurality of (two in the example illustrated in the figure) wafers in each processing chamber 50.

The loading/unloading port 51 and the loading/unloading port 53 described above are provided for each first processing space S21.

In each processing chamber 50, the two arranged first processing spaces S21 and the two arranged second processing spaces S22 are separated by, for example, partition walls.

Inside each first processing space S21 and inside each second processing space S22, a stage 55 as a substrate support table is provided to support the wafer W during a chemical vapor liquid film forming process or an annealing process. A temperature control mechanism (not illustrated) is provided for each stage 55 in order to control the temperature of the wafer W to a temperature suitable for the chemical vapor liquid film forming process or the annealing process. The temperature control mechanism is, for example, a resistance heater embedded in the stage 55.

Inside each first processing space S21 and inside each second processing space S22, for example, a plurality of lift pins (not illustrated) are erected in order to deliver the wafer W between the stage 55 and the wafer transfer mechanism 60.

In the first processing space S21, a flowable intermediate is generated by a chemical vapor phase liquid film forming process to fill minute recesses formed on the surface of the wafer W. In the second processing space S22, an annealing process is performed on the wafer W to turn the flowable intermediate into an insulating film.

In the chemical vapor liquid film forming process, for example, an oxygen-containing silicon compound gas and a non-oxidizing hydrogen-containing gas are reacted with each other in a state in which at least the hydrogen-containing gas is plasmarized to form a film of a flowable silanol compound on the wafer W.

Examples of the oxygen-containing silicon compound gas include tetramethoxysilane (TMOS; Si(OCH₃)₄) and tetraethoxysilane (TEOS; Si(OC₂H₅)₄). These compounds may be used alone or in combination of two or more.

Examples of the non-oxidizing hydrogen-containing gas may include a H₂ gas, a NH₃ gas, and a SiH₄ gas, which may be used alone or in combination of two or more.

In order to enable the above-described chemical vapor liquid film forming process, a gas supplier (not illustrated) configured to supply a processing gas, such as an oxygen-containing silicon compound gas or a non-oxidizing hydrogen-containing gas, to the first processing spaces S21 is connected to the processing chambers 50. When a processing gas is required for the annealing process, a gas supplier (not illustrated) configured to supply the processing gas for the annealing process to the second processing spaces S22 is also connected to the processing chambers 50.

In order to enable the above-described chemical vapor liquid film forming process, the first processing spaces S21 are each provided therein with a gas shower head (not illustrated) as a gas introduction part for introducing a processing gas, such as an oxygen-containing silicon compound gas or a non-oxidizing hydrogen-containing gas, into the first processing spaces S21.

In order to enable the above-described chemical vapor liquid film forming process, a radio-frequency power supply (not illustrated) configured to supply radio-frequency power for plasma generation is connected to the gas shower head.

The processing chambers 50 are each provided with an exhauster (not illustrated) in order to evacuate the first processing spaces S21 and the second processing spaces S22. The exhauster may be shared by the first processing spaces S21 and the second processing spaces S22, or may be provided separately for each of the first processing spaces S21 and the second processing spaces S22.

The lower the temperatures of wafers W during a chemical vapor liquid film forming process, i.e., the temperatures of the stages 55 in the first processing spaces S21, the higher the fluidity of the intermediates formed on the surfaces of the wafers W by the chemical vapor liquid film forming process. In addition, the higher the temperatures of the wafers W during an annealing process, i.e., the higher the temperatures of the stages 55 in the second processing spaces S22, it is possible to turn the intermediates into insulating films in a short period of time.

Therefore, the temperatures of the stages 55 in the first processing spaces S21 are set to, for example, 100 degrees C. or less, and the temperatures of the stages 55 in the second processing spaces S22 are set to, for example, 150 to 400 degrees C.

A controller U is provided in the wafer processing apparatus 1 configured as described above. The controller U is configured with, for example, a computer including a CPU, a memory, or the like, and includes a program storage part (not illustrated). The program storage part stores a program and the like for controlling the wafer transfer mechanism 30, the wafer transfer mechanism 60, the gate valves 52 and 54, and the like, to realize wafer processing in the wafer processing apparatus 1, which will be described later. The program may be recorded in a computer-readable storage medium and may be installed in the controller U from the storage medium. In addition, a portion or all of the program may be implemented by dedicated hardware (a circuit board).

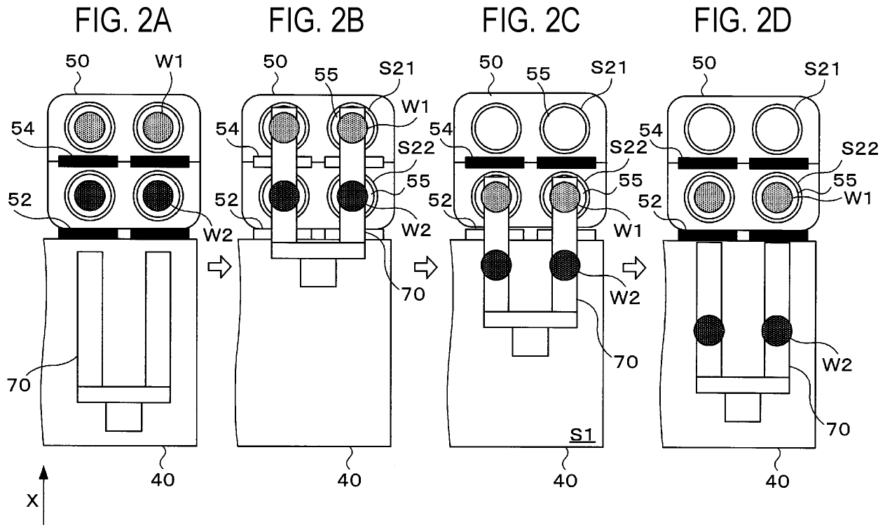

Next, wafer processing performed using the wafer processing apparatus 1 configured as described above, specifically, wafer processing from when the chemical vapor phase liquid film forming process in the first processing spaces S21 and the annealing process in the second processing spaces S22 are performed, will be described with reference to FIGS. 2A to 4B. FIGS. 2A to 4B are views illustrating the state of the wafer holders 70 in each operation of the above-described wafer processing. In FIGS. 2A to 4B, gate valves in the open state are illustrated in white, and gate valves in the closed state are illustrated in black. Each of the following operations is performed under the control of the controller U.

### (A1: Execution of Chemical Vapor Liquid Film Forming Process and Annealing Process)

During the execution of the chemical vapor liquid film forming process in the first processing spaces S21 and the annealing process in the second processing spaces S22, the gate valves 52 and 54 remain closed as illustrated in FIG. 2A.

(A2: Receipt of Wafers W1 subjected to Chemical Vapor Liquid Film Forming Process and Wafers W2 Subjected to Annealing Process)

When the chemical vapor liquid film forming process and the annealing process are completed, the gate valves 52 and 54 remain opened as illustrated in FIG. 2B. Subsequently, the wafer holders 70 move to one side in the wafer loading/unloading direction (the positive side in the X direction in the figure) and are inserted into the processing chamber 50 from the vacuum transfer chamber 40. Specifically, this movement is performed until the tip portions of the wafer holders 70 pass through the second processing spaces S22 and reach the interiors of the first processing spaces S21. Then, the wafer holders 70 simultaneously receive wafers W1 subjected to the chemical vapor liquid film forming process (hereinafter, sometimes abbreviated as the “wafer W1 subjected to the film forming process”) and wafers W2 subjected to the annealing process. In other words, the wafer holders 70 also receive the wafers W2 subjected to the annealing process in the second processing spaces S22 at the timing of receiving the wafers W1 subjected to the chemical vapor liquid film forming process in the first processing spaces S21. The wafer holders 70 receive the wafers W1 subjected the chemical vapor liquid film forming process at the tip portions thereof, and receive the wafers W2 subjected to the annealing process at the base portions thereof.

Receipt of the wafers W1 subjected to the chemical vapor liquid film forming process by the wafer holders 70 in the first process spaces S21 is performed, for example, as follows. First, the stages 55 are lowered from the processing positions to the standby positions, and the wafers W1 subjected the chemical vapor liquid film forming process are transferred from the stages 55 to the lift pins (not illustrated). Thereafter, the movement (insertion) of the wafer holders 70 is performed so that the wafer holders 70 are located between the wafers W on the lift pins and the stages 55. Then, the lift pins are lowered, whereby the wafers W1 subjected to the chemical vapor liquid film forming process on the lift pins are received by the wafer holders 70.

The method of receiving the wafers W2 subjected to the annealing process by wafer holders 70 in second processing spaces S22 is the same as the method of receiving the wafers W1 subjected to the chemical vapor liquid film forming process by the wafer holders 70 in the first processing spaces S21, for example, as follows. First, the lift pins (not illustrated) are raised, and the wafers W2 subjected to the annealing process is delivered from the stages 55 to the lift pins (not illustrated). Thereafter, the movement of the wafer holders 70 is performed so that the wafer holders 70 are located between the wafers W on the lift pins and the stages 55. Then, the lift pins are lowered, whereby the wafers W2 on the lift pins subjected to the annealing process are received by the wafer holders 70.

In operation A7 and the like, which will be described later, the wafer holders 70 move in the second processing spaces S22 in the state in which the wafers W are placed on the stages 55 in the second processing spaces S22. Therefore, the stages 55 in the second processing spaces S22 may be fixed below the spaces in which the wafer holders 70 are movable.

The driving force for raising/lowering the stages 55 and raising/lowering the lift pins required for receiving the wafers W by the wafer holders 70 in the first processing spaces S21 and the second processing spaces S22 is provided by a drive part including a motor or the like (not illustrated), and the drive part is controlled by the controller U.

(A3: Transfer of Wafers W1 subjected to Chemical Vapor Liquid Film Forming Process)

Subsequently, the wafer holders 70 move in the wafer loading/unloading direction (the X direction in the figure), and transfer the wafers W1 subjected to the chemical vapor liquid film forming process from the first processing spaces S21 to the second processing spaces S22 without passing through the vacuum transfer space S1. Specifically, the wafer holders 70 holding both the wafers W1 subjected to the film forming process and the wafers W2 subjected to the annealing process move to the other side in the loading/unloading direction (the negative side in the X direction in the figure). As illustrated in FIG. 2C, this movement is performed until the tip portions that hold the wafers W subjected to the film forming process in the wafer holders 70 are located in the second processing spaces S22 and the wafers W1 subjected to the film forming process are located above the stages 55 in the second processing spaces S22. That is, in this operation, the wafers W1 subjected to the film forming process are held by the wafer holders 70 that also hold the wafers W2 subjected to the annealing process, and are transferred from the first processing spaces S21 to the second processing spaces S22.

In this operation, with the transfer (movement) of the wafers W2 subjected to the annealing process held, the wafers W2 subjected to the annealing process and held on the base portions of the wafer holders 70 are unloaded to the vacuum transfer chamber 40.

After the movement of the wafers W1 subjected to the film forming process and the unloading of the wafers W2 subjected to the annealing process, the gate valves 54 are closed. At the same time, the wafers W1 subjected to the film forming process are delivered from the wafer holders 70 in the second processing spaces S22. Specifically, for example, the lift pins (not illustrated) in the second processing spaces S22 are raised, and the wafers W1 subjected to the film forming process are delivered onto the lift pins.

### (A4: Pulling-Out of Wafer Holders 70)

Thereafter, the wafer holders 70 further move to the other side in the wafer loading/unloading direction (the negative side in the X direction in the figure), and the entire wafer holders 70 are pulled out from the processing chamber 50, as illustrated in FIG. 2D. Then, the gate valves 52 are closed. At the same time, the lift pins (not illustrated) in the second processing spaces S22 are lowered, and the wafers W1 subjected to the film forming processing are placed on the stages 55 in the second processing spaces S22. Thereafter, the annealing process for the wafers W1 subjected the film forming process is initiated.

### (A5: Unloading of Wafers W2 Subjected to Annealing Process)

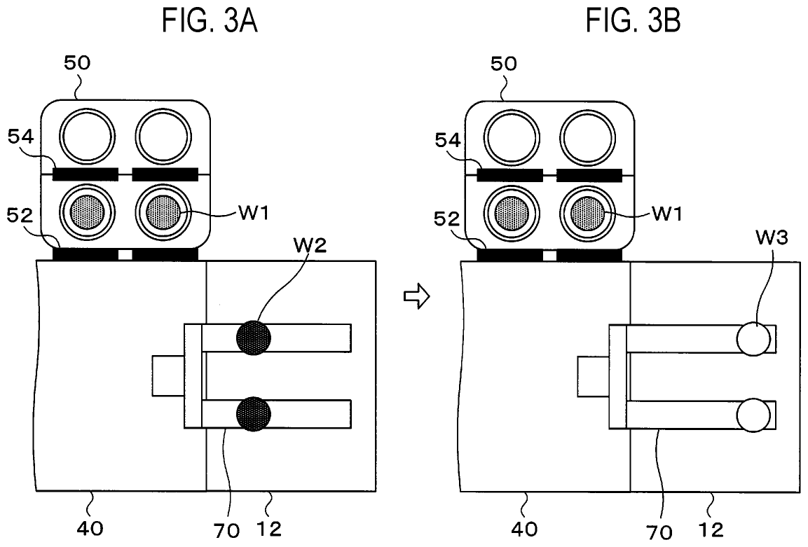

Subsequently, the wafer holders 70 are inserted into the load-lock chamber 12 as illustrated in FIG. 3A. Then, the wafers W2 subjected to the annealing process are delivered from the base portions of the wafer holders 70 in the load-lock chamber 12. Specifically, for example, the lift pins (not illustrated) in the load-lock chamber 12 are raised, and the wafers W2 subjected to the annealing process are transferred onto the lift pins. The wafers W2 subjected to the annealing process and delivered to the lift pins are transferred from the load-lock chamber 12 to a FOUP 21 at a predetermined timing.

### (A6: Receipt of Unprocessed Wafers W3)

Subsequently, as illustrated in FIG. 3B, in the load-lock chamber 12, receipt of wafers W3 to be subjected to the chemical vapor liquid film forming process by the tip portions of the wafer holders 70, i.e., receipt of unprocessed wafers W3, is performed. Specifically, the lift pins (not illustrated) in the load-lock chamber 12, which have previously been supporting the unprocessed wafer W3 at the upper ends thereof, are lowered, thus causing the unprocessed wafers W3 on the lift pins to be delivered to the tip portions of the wafer holders 70.

### (A7: Transfer of Unprocessed Wafers W3)

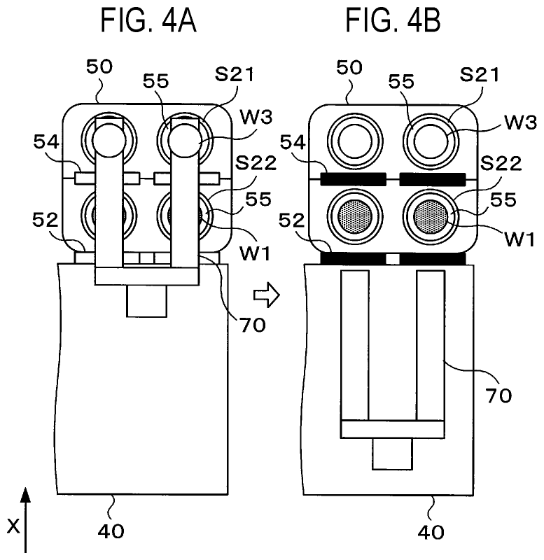

Subsequently, as illustrate in FIG. 4A, the gate valves 52 and 54 are opened. Then, in the state in which the wafers W1 subjected to the film forming process are located in the second processing spaces S22, the wafer holders 70 holding only the unprocessed wafers W3 are inserted into the processing chamber 50, and the unprocessed wafers W3 are transferred to the first processing spaces S21. Thereafter, the unprocessed wafers W3 are delivered from the wafer holders 70 in the first processing spaces S21. Specifically, for example, the lift pins (not illustrated) in the first processing spaces S21 are raised, and the unnecessary wafers W3 are delivered onto the lift pins.

### (A8: Pulling-Out of Wafer Holders 70)

Thereafter, the wafer holders 70 move to the other side in the wafer loading/unloading direction (the negative side in the X direction in the figure), and the entire wafer holders 70 are pulled out from the processing chamber 50, as illustrated in FIG. 4B. Then, the gate valves 52 and 54 are closed. At the same time, the lift pins (not illustrated) in the first processing spaces S21 are lowered, and the unprocessed wafers W3 are placed on the stages 55 in the first processing spaces S21. Thereafter, the chemical vapor liquid film forming process for the unprocessed wafers W3 is initiated.

Thereafter, the process is returned to the above-described operation A1, and operations A1 to A8 are repeated.

As described above, in the present embodiment, in the wafer processing apparatus 1, the first processing spaces S21 and the second processing spaces S22 are aligned in the wafer loading/unloading direction by the wafer transfer mechanism 60 via the loading/unloading port 51. Therefore, after the wafer holders 70 receive the wafers W1 subjected to the chemical vapor liquid film forming process in the first processing spaces S21, by moving the wafer holders 70 in the wafer loading/unloading direction, it is possible to transfer the wafers W1 subjected to the film forming process to the second processing spaces S22 without passing through the vacuum transfer space S1. Therefore, the vacuum transfer space S1 is not adversely affected by the wafers W1 subjected to the chemical vapor liquid film forming process and to be subjected the annealing process. Specifically, for example, it is possible to prevent a component volatilized from an intermediate product, which is formed on the surfaces of the wafers W in the chemical vapor liquid film forming process, from adhering to the surface of the inner wall of the vacuum transfer chamber 40. In addition, it is possible to prevent the wafers W1 subjected to the chemical vapor liquid film forming process and to be subjected to the annealing process from being adversely affected by the atmosphere of the vacuum transfer space S1. Furthermore, it is possible to prevent a harmful gas from being released to the air atmosphere or the like from the wafers W1 subjected to the chemical vapor liquid film forming process and to be subjected to the annealing process.

Furthermore, according to the present embodiment, there are the following effects. That is, as a wafer processing apparatus that performs both a chemical vapor liquid film forming process and an annealing process, an apparatus in which, unlike the present embodiment, a first processing space in which the chemical vapor liquid film forming process is performed and a second processing space in which the annealing process is performed are provided in separate processing chambers, respectively, and the processing chambers are connected to each other via a vacuum transfer chamber is conceivable. In this wafer processing apparatus (hereinafter, referred to as a comparative wafer processing apparatus), the wafer subjected to the chemical vapor liquid film forming process is transferred from the first processing space to the second processing space via the vacuum transfer chamber. In contrast, in the present embodiment, it is possible to transfer the wafers W1 subjected to a chemical vapor liquid film forming process from the first processing spaces S21 to the second processing spaces S22 without passing through the vacuum transfer chamber 40. Therefore, it is possible to shorten the time for transferring the wafers W1 subjected to the chemical vapor liquid film forming process from the first processing spaces S21 to the second processing spaces S22. Therefore, it is possible to improve throughput in the wafer processing apparatus 1. Specifically, in the present embodiment, the time for transferring the wafers W1 subjected the chemical vapor liquid film forming process from the first processing spaces S21 to the second processing spaces S22 is reduced by at least about 2 to 3 seconds compared to the comparative wafer processing apparatus. The time required for a chemical vapor liquid film forming process is, for example, about 100 seconds. Thus, the fact that it is possible to shorten the time required for transferring the wafers W1 subjected to the chemical vapor liquid film forming process from the first processing spaces S21 to the second processing spaces S22 by about 2 to 3 seconds as described above is very substantial from the viewpoint of the throughput of the wafer processing apparatus 1.

In addition, in the present embodiment, the wafer holders 70 have a length that is capable of extending over the first processing spaces S21 and the second processing spaces S22. Therefore, at the timing of receiving the wafers W1 subjected to the chemical vapor liquid film forming process in the first processing spaces S21, the wafer holders 70 are also capable of receiving the wafers W2 subjected to the annealing process in the second processing spaces S22. Therefore, compared to the case where the timing of receiving the wafer W1 subjected to the chemical vapor liquid film forming process by the wafer holder 70 in the first processing space S21 and the timing of receiving the wafer W2 subjected to the annealing process by the wafer holder 70 in the second processing space S22 are different from each other, it is possible to further improve the throughput in the wafer processing apparatus 1.

In the present embodiment, the chemical vapor liquid film forming process and the annealing process are performed in separate processing spaces. Specifically, the chemical vapor liquid film forming process and the annealing process are performed on separate stages 55, respectively. Therefore, there is no need to change the temperatures of the stages 55 between the chemical vapor liquid film forming process and the annealing process. Therefore, even if the stage temperatures, i.e., the processing temperatures set in the chemical vapor liquid film forming process and the annealing process are significantly different from each other, it is possible to perform a series of processes including the chemical vapor liquid film forming process and the annealing process in a short period of time.

The wafer processing apparatus 1 according to the present embodiment is appropriately used when the annealing process is longer than the chemical vapor liquid film forming process, that is, when the second process is longer than the first process. In addition, it is possible to adjust the length of time of the chemical vapor liquid film forming process by the flow rate of a processing gas, the output of radio-frequency power for plasma generation, or the like.

### Second Embodiment

In the wafer processing apparatus 1 according to the first embodiment, the wafer transfer mechanism 60 is provided with a pair of wafer holders 70. In other words, one wafer holding unit including a pair of wafer holders 70 is provided at the tip end of the transfer arm 61 of the wafer transfer mechanism 60.

In contrast, in the wafer processing apparatus according to the present embodiment, two wafer holding units each including a pair of wafer holders 70 are provided at the tip end of the transfer arm of the wafer transfer mechanism. In the following description, one of the wafer holding units will be referred to as a “wafer holding unit 80” and the other will be referred to as a “wafer holding unit 81.”

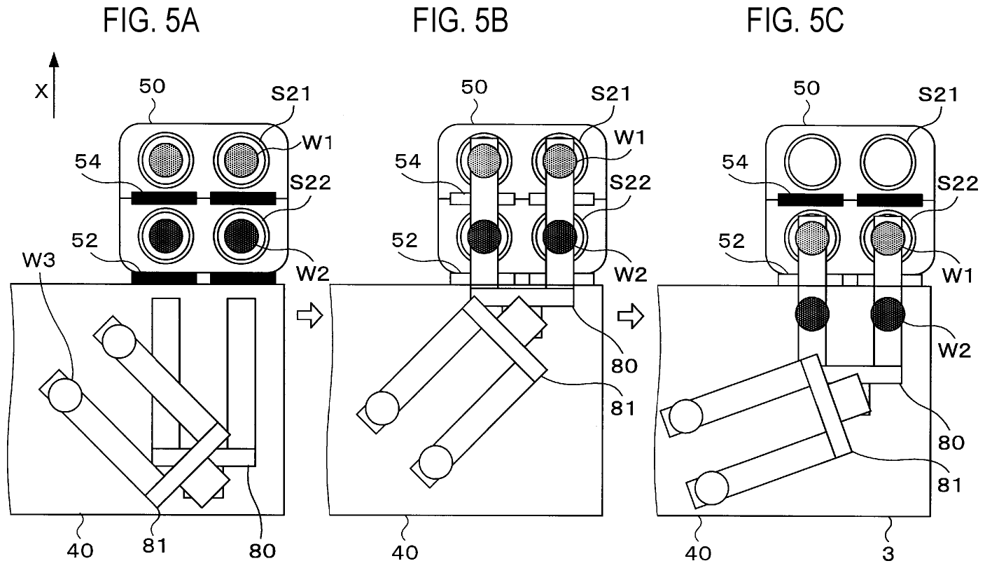

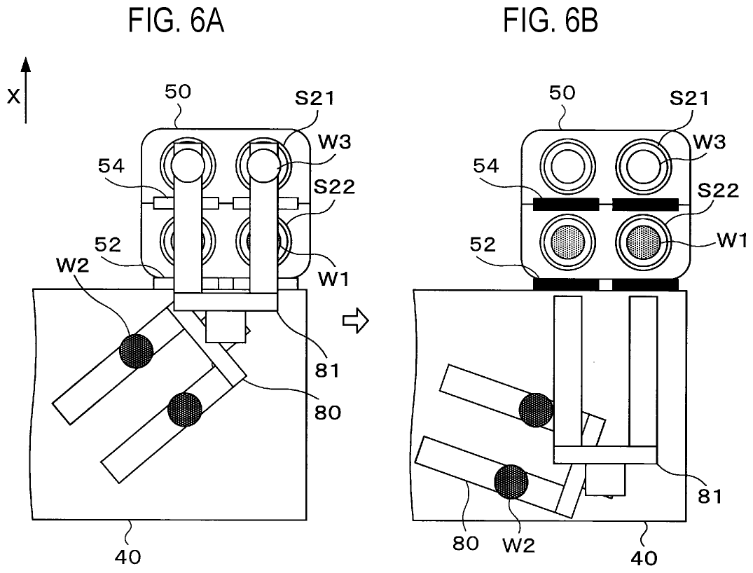

FIGS. 5A to 6B are views illustrating the states of the wafer holding units 80 and 81 in each operation of wafer processing performed by using the wafer processing apparatus according to the second embodiment.

### (B1: Execution of Chemical Vapor Liquid Film Forming Process and Annealing Process)

During the execution of the chemical vapor liquid film forming process in the first processing spaces S21 and the annealing process in the second processing spaces S22, the gate valves 52 and 54 remain closed as illustrated in FIG. 5A. At this time, the wafer holding unit 80 does not hold wafers W, but the wafer holding unit 81 holds unprocessed wafers W3 at the tip portions thereof.

(B2: Receipt of Wafers W1 subjected to Chemical Vapor Liquid Film Forming Process and Wafers W2 Subjected to Annealing Process)

When the chemical vapor liquid film forming process and the annealing process are completed, the gate valves 52 and 54 are opened as illustrated in FIG. 5B. Subsequently, the wafer holding unit 80 moves to one side in the wafer loading/unloading direction (the positive side in the X direction in the figure) and is inserted into a processing chamber 50 from the vacuum transfer chamber 40. At this time, the wafer holding unit 81 remains located in the vacuum transfer chamber 40. Then, the wafer holding unit 80 simultaneously receives wafers W1 subjected to a film forming process and wafers W2 subjected to an annealing process.

### (B3: Transfer of Wafers W1 Subjected to Film Forming Process)

Subsequently, as illustrated in FIG. 5C, the wafer holding unit 80 moves to the other side in the wafer loading/unloading direction (the negative side in the X direction in the figure), and transfers the wafers W1 subjected to the film forming process from the first processing spaces S21 to the second processing spaces S22 without passing through the vacuum transfer space S1. At this time, the wafer holding unit 80 also holds the wafers W2 subjected to the annealing process, and the wafer holding unit 81 continues to be located in the vacuum transfer chamber 40.

After the wafers W1 subjected to the film forming process are transferred to the second processing spaces S22, the gate valves 54 are closed. At the same time, the wafers W1 subjected to the film forming process are delivered from the wafer holding unit 80 in the second processing spaces S22. Specifically, for example, the lift pins (not illustrated) in the second processing spaces S22 are raised, and the wafers W1 subjected to the film forming process are delivered onto the lift pins.

### (B4: Pulling-Out of Wafer Holding Unit 80 and Transfer of Unprocessed Wafers W3)

Thereafter, the entire wafer holding unit 80 is pulled out from the processing chamber 50 as illustrated in FIG. 6A. In addition, the lift pins (not illustrated) in the second processing spaces S22 are lowered, and the wafers W1 subjected to the film forming processing are placed on the stages 55 in the second processing spaces S22. Thereafter, the annealing process for the wafers W1 subjected to the film forming process is initiated.

Subsequently, the gate valves 54 are in the open state. Then, in the state in which the wafers W1 subjected to the film forming process are located in the second processing spaces S22, the wafer holding unit 81 holding only the unprocessed wafers W3 are inserted into the processing chamber 50, and the unprocessed wafers W3 are transferred to the first processing spaces S21. Thereafter, the unprocessed wafers W3 are delivered from the wafer holding unit 81 in the first processing spaces S21. Specifically, for example, the lift pins (not illustrated) in the first processing spaces S21 are raised, and the unnecessary wafers W3 are delivered onto the lift pins.

### (B5: Pulling-Out of Wafer Holding Unit 81)

Thereafter, the wafer holding unit 81 moves to the other side in the wafer loading/unloading direction (the negative side in the X direction in the figure), and the entire wafer holding unit 81 is pulled out from the processing chamber 50, as illustrated in FIG. 6B. Then, the gate valves 52 and 54 are closed. At the same time, the lift pins (not illustrated) in the first processing spaces S21 are lowered, and the unprocessed wafers W3 are placed on the stages 55 in the first processing spaces S21. Thereafter, the chemical vapor liquid film forming process for the unprocessed wafers W3 is initiated.

### (B6: Unloading of Wafers W2 Subjected to Annealing Process)

Subsequently, the wafer holding unit 80 is inserted into the load-lock chamber 12. Then, the wafers W2 subjected to the annealing process are delivered from the base portions of the wafer holding unit 80 in the load-lock chamber 12.

### (B7: Receipt of Unprocessed Wafers W3)

Subsequently, the wafer holding unit 80 receives the unprocessed wafers W3 at the tip portions thereof in the load-lock chamber 12.

Thereafter, the process is returned to the above-described operation B1, and operations B1 to B7 are repeated. The operations of the wafer holding unit 80 and the wafer holding unit 81 may be performed simultaneously as long as the operations thereof do not interfere with each other.

In the present embodiment as well, it is possible to transfer the wafers W1 subjected to the chemical vapor liquid film forming process to the second processing spaces S22 without passing through the vacuum transfer space S1. Therefore, the vacuum transfer space S1 is not adversely affected by the wafers W1 subjected to the chemical vapor liquid film forming process and to be subjected to the annealing process. In addition, it is possible to suppress the wafers W1 subjected to the chemical vapor liquid film forming process and to be subjected to the annealing process from being adversely affected by the atmosphere of the vacuum transfer space S1.

According to the present embodiment, it is possible to shorten the time from the completion of the chemical vapor liquid film forming process for the wafers W to the initiation of the chemical vapor liquid film forming process for the subsequent wafers W, which makes it possible to further improve the throughput.

The wafer processing apparatus according to the present embodiment may be appropriately used when the time required for the chemical vapor liquid film forming process is close to the time required for the annealing process.

### Third Embodiment

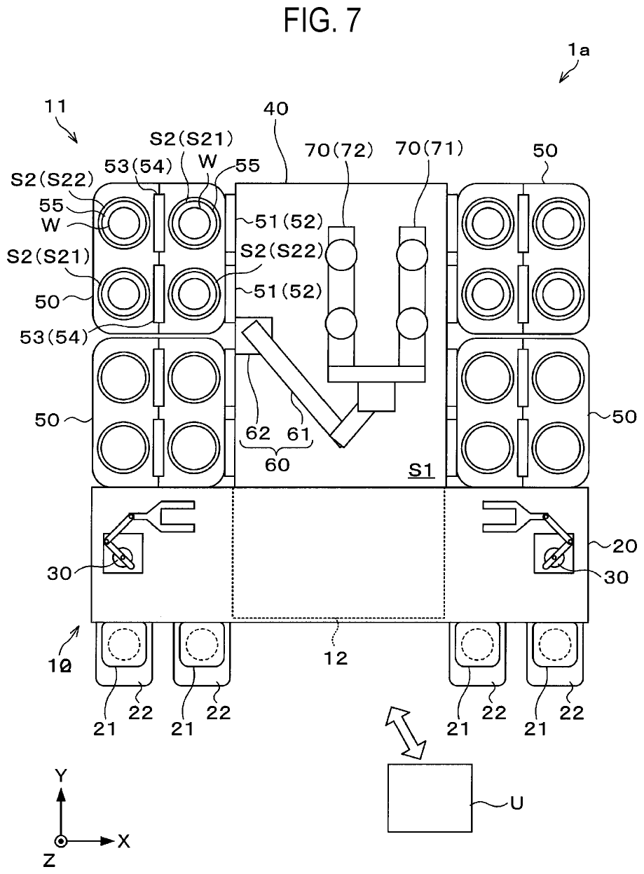

FIG. 7 is a plan view schematically illustrating the outline of the configuration of a wafer processing apparatus according to a third embodiment.

In the wafer processing apparatus 1 according to the first embodiment, in the wafer loading/unloading direction (the X direction in the figure) via the loading/unloading port 51, the first processing spaces S21 are located on the rear side with respect to the vacuum transfer chamber 40, and the second processing spaces S22 are located on the front side with respect to the vacuum transfer chamber 40.

In contrast, in the wafer processing apparatus 1a according to the third embodiment, as illustrated, in the wafer loading/unloading direction (the X direction in the figure) via the loading/unloading ports 51, the first processing spaces S21 are located on the front side with respect to the vacuum transfer chamber 40, and the second processing spaces S22 are located on the rear side with respect to the vacuum transfer chamber 40.

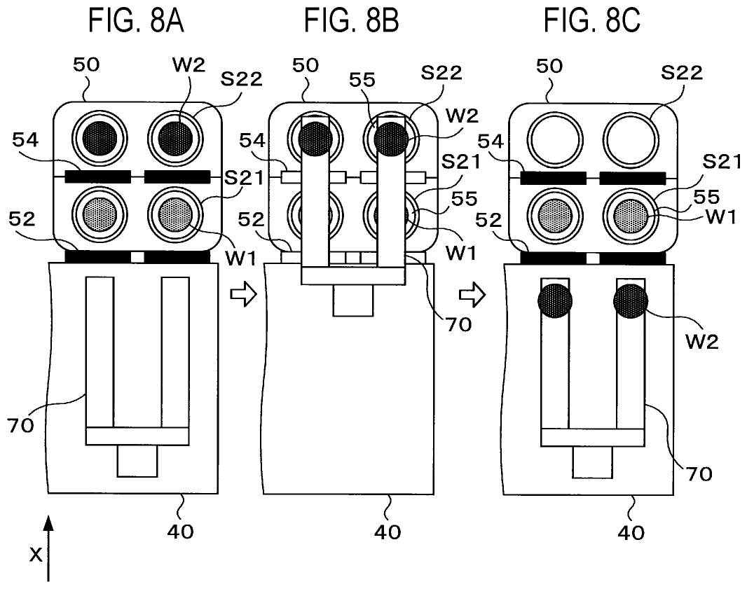

FIGS. 8A to 10C are views illustrating the states of the wafer holders 70 in each operation of wafer processing performed by using the wafer processing apparatus 1a according to the third embodiment.

### (C1: Execution of Chemical Vapor Liquid Film Forming Process and Annealing Process)

During the execution of the chemical vapor liquid film forming process in the first processing spaces S21 and the annealing process in the second processing spaces S22, the gate valves 52 and 54 remain closed as illustrated in FIG. 8A.

### (C2: Receipt of Wafers W2 Subjected to Annealing Process)

When the chemical vapor liquid film forming process and the annealing process are completed, the gate valves 52 and 54 are opened as illustrated in FIG. 8B. Subsequently, the wafer holders 70 move to one side in the wafer loading/unloading direction (the positive side in the X direction in the figure) and are inserted into a processing chamber 50 from the vacuum transfer chamber 40. Specifically, this movement is performed until the tip portions of the wafer holders 70 pass through the first processing spaces S21 and reach the interiors of the second processing spaces S22. Then, the wafer holders 70 receive only the wafers W2 subjected to the annealing process at the tip portions thereof.

### (C3: Pulling-Out of Wafer Holders 70)

Thereafter, the wafer holders 70 move to the other side in the wafer loading/unloading direction (the negative side in the X direction in the figure) in the state of holding only the wafers W2 subjected to the annealing process, and the entire wafer holders 70 are pulled out from the processing chamber 50, as illustrated in FIG. 8C. Then, the gate valves 52 and 54 are closed.

### (C4: Unloading of Wafers W2 Subjected to Annealing Process)

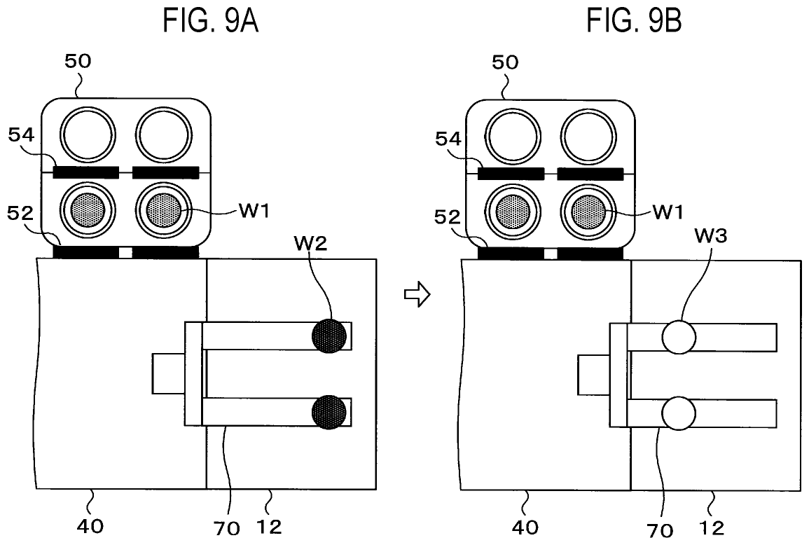

Subsequently, the wafer holders 70 are inserted into the load-lock chamber 12 as illustrated in FIG. 9A. Then, the wafers W2 subjected to the annealing process are delivered from the tip portions of the wafer holders 70 in the load-lock chamber 12. Specifically, for example, the lift pins (not illustrated) in the load-lock chamber 12 are raised, and the wafers W2 subjected to the annealing process are transferred onto the lift pins.

### (C5: Receipt of Unprocessed Wafers W3)

Subsequently, as illustrated in FIG. 9B, in the load-lock chamber 12, receipt of wafers W3 to be subjected to the chemical vapor liquid film forming process by the base portions of the wafer holders 70, i.e., receipt of unprocessed wafers W3, is performed. Specifically, the lift pins (not illustrated) in the load-lock chamber 12, which have previously been supporting the unprocessed wafer W3 at the upper ends thereof, are lowered, thus causing the unprocessed wafers W3 on the lift pins to be delivered to the base portions of the wafer holders 70.

### (C6: Receipt of Wafers W1 Subjected to Chemical Vapor Liquid Film Forming Process)

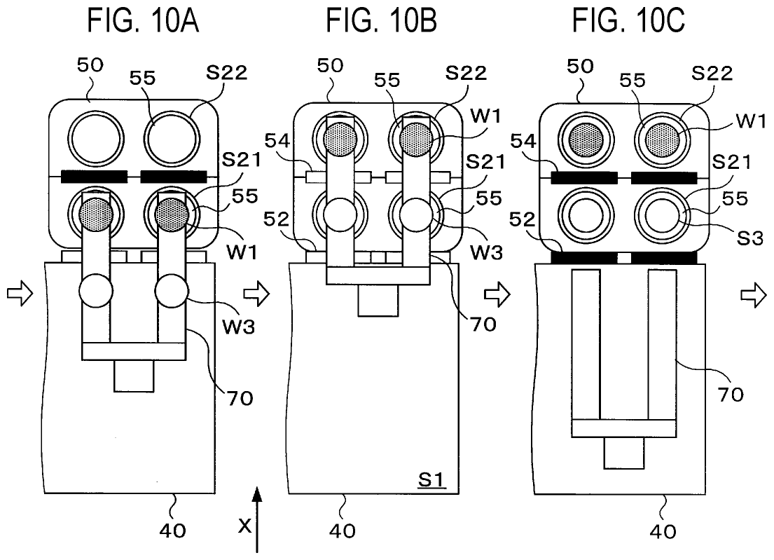

Subsequently, as illustrated in FIG. 10A, the gate valves 52 are opened and the tip portions of the wafer holders 70 are inserted into the first processing spaces S21 of the processing chamber 50. Then, the wafer holders 70 receive the wafers W1 subjected to the film forming process at the tip portions thereof. At this time, unprocessed wafers W3 are held on the base portions of the wafer holders 70. That is, in this operation, the wafer holders 70 holding the unprocessed wafers W3 receive the wafers W1 subjected to the film forming processes in the first processing spaces S21.

### (C7: Transfer of Wafers W1 Subjected to Film Forming Process and Unprocessed Wafers W3)

Subsequently, as illustrated in FIG. 10B, the gate valves 54 are opened, and the wafer holders 70 move to one side in the wafer loading/unloading direction (the positive side in the X direction in the figure). As a result, the wafers W1 subjected to the film forming process are transferred from the first processing spaces S21 to the second processing spaces S22 without passing through the vacuum transfer space S1, and the unprocessed wafers W3 are transferred to the first processing spaces S21. Then, the wafer holders 70 simultaneously deliver the wafers W1 subjected to the film forming process and the unprocessed wafers W3. In other words, at the timing of delivering the wafers W1 subjected to the film forming process and held on the tip portions of the wafer holders 70 in the second processing spaces S22, the wafer holders 70 also deliver the unprocessed wafers W3 held on the base portions thereof in the first processing spaces S21. In the delivery of the wafers W1 subjected to the film forming process in the second processing spaces S22, the lift pins (not illustrated) in the second processing spaces S22 are raised, and the wafers W1 subjected to the film forming process are delivered onto the lift pins. In the delivery of the unprocessed wafers W3 in the first processing spaces S21, the lift pins (not illustrated) in the first processing spaces S21 are raised, and the unprocessed wafers W3 are delivered onto the lift pins.

### (C8: Pulling-Out of Wafer Holders 70)

Thereafter, the wafer holders 70 move to the other side in the wafer loading/unloading direction (the negative side in the X direction in the figure), and the entire wafer holders 70 are pulled out from the processing chamber 50, as illustrated in FIG. 10C. Then, the gate valves 52 and 54 are closed. At the same time, the lift pins (not illustrated) in the first processing spaces S21 and the lift pins (not illustrated) in the second processing spaces S22 are lowered, and the wafers W1 subjected to the film forming process are placed on the stages 55 in the second processing spaces S22 and the unprocessed wafers W3 are placed on the stages 55 in the first processing spaces S21. Thereafter, the annealing process for the wafers W1 subjected to the film forming process and the chemical vapor liquid film forming process for the unprocessed wafers W3 are initiated.

Thereafter, the process is returned to the above-described operation C1, and operations C1 to C8 are repeated.

In the present embodiment as well, it is possible to transfer the wafers W1 subjected to the chemical vapor liquid film forming process to the second processing spaces S22 without passing through the vacuum transfer space S1. Therefore, the vacuum transfer space S1 is not adversely affected by the wafers W1 subjected to the chemical vapor liquid film forming process and to be subjected to the annealing process. In addition, it is possible to suppress the wafers W1 subjected to the chemical vapor liquid film forming process and to be subjected to the annealing process from being adversely affected by the atmosphere of the vacuum transfer space S1.

Furthermore, in the present embodiment, since there is a time period from the completion of the chemical vapor liquid film forming process to the initiation of the annealing process, during this time period, a process other than a chemical vapor liquid film forming process using plasma may be performed on the wafers W1 subjected to the chemical vapor liquid film forming process in the first processing spaces S21.

### Fourth Embodiment

In a wafer processing apparatus according to a fourth embodiment, the first processing spaces S21 and the second processing spaces S22 are located as in the wafer processing apparatus according to the third embodiment. Specifically, in the wafer loading/unloading direction (the X direction in the figure) via the loading/unloading port 51, the first processing spaces S21 are located on the front side with respect to the vacuum transfer chamber 40, and the second processing spaces S22 are located on the rear side with respect to the vacuum transfer chamber 40. As in the wafer processing apparatus according to the second embodiment, the wafer processing apparatus according to the fourth embodiment is provided with two wafer holding units (wafer holding units 80 and 81) each including a pair of wafer holders 70.

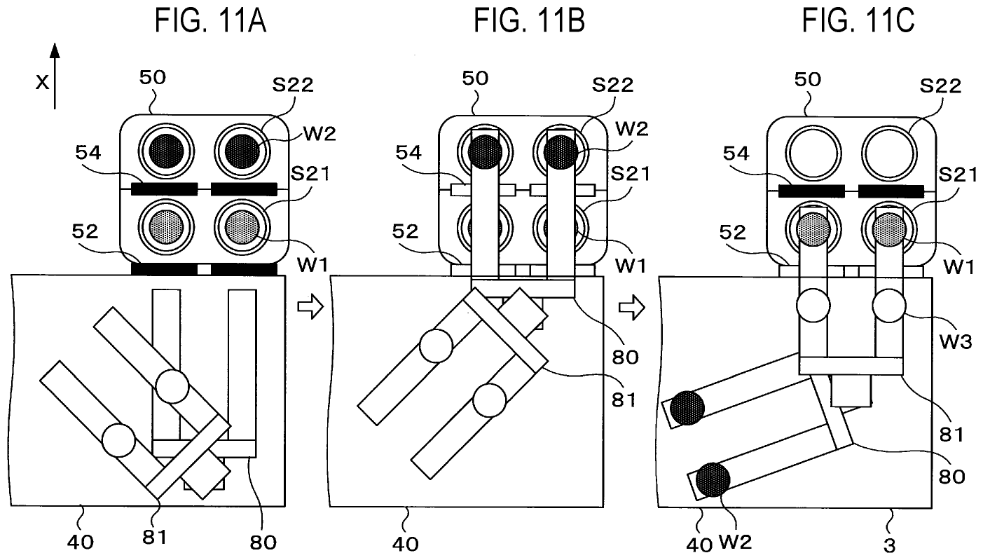

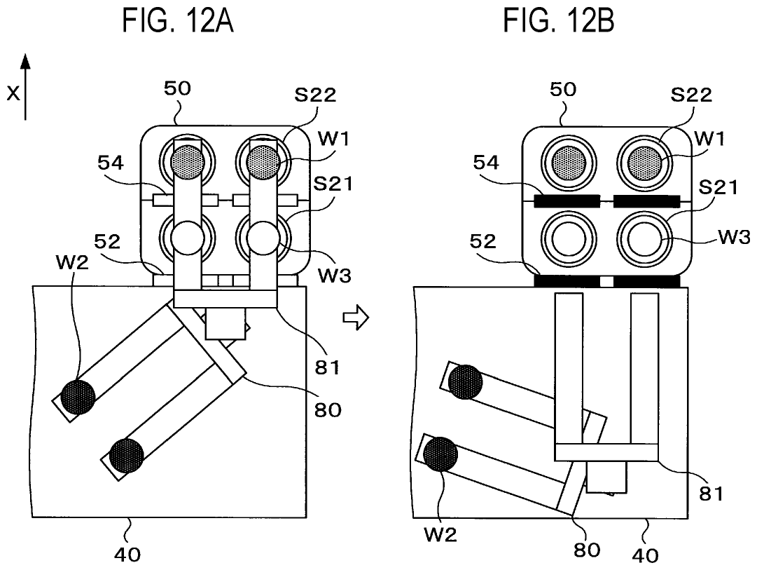

FIGS. 11A to 12B are views illustrating the states of the wafer holding units 80 and 81 in each operation of wafer processing performed by using the wafer processing apparatus according to the fourth embodiment.

### (D1: Execution of Chemical Vapor Liquid Film Forming Process and Annealing Process)

During the execution of the chemical vapor liquid film forming process in the first processing spaces S21 and the annealing process in the second processing spaces S22, the gate valves 52 and 54 remain closed as illustrated in FIG. 11A. At this time, the wafer holding unit 80 does not hold wafers W, but the wafer holding unit 81 holds unprocessed wafers W3 at the base portions thereof.

### (D2: Receipt of Wafers W2 Subjected to Annealing Process)

When a chemical vapor liquid film forming process and an annealing process are completed, the gate valves 52 and 54 are opened as illustrated in FIG. 11B. Subsequently, the wafer holding unit 80 moves to one side in the wafer loading/unloading direction (the positive side in the X direction in the figure) and is inserted into a processing chamber 50 from the vacuum transfer chamber 40. At this time, the wafer holding unit 81 remains located in the vacuum transfer chamber 40. Then, the wafer holders 70 receive only the wafers W2 subjected to the annealing process at the tip portions thereof.

### (D3: Pulling-Out of Wafer Holding Unit 80 and Receipt of Unprocessed Wafers W3)

Subsequently, as illustrated in FIG. 11C, the entire wafer holding unit 80 is pulled out from the processing chamber 50, the gate valves 54 are closed, and the tip portions of the wafer holding unit 81 are inserted into the first processing spaces S21. Then, the wafer holding unit 81 receives the wafers W1 subjected to the film forming process at the tip portions thereof. At this time, unprocessed wafers W3 are held on the base portions of the wafer holders 70 of the wafer holding unit 81.

### (D4: Transfer of Wafers W1 Subjected to Film Forming Process and Transfer of Unprocessed Wafers W3)

Subsequently, as illustrated in FIG. 12A, the gate valves 54 are opened, and the wafer holding unit 81 moves to one side in the wafer loading/unloading direction (the positive side in the X direction in the figure). As a result, the wafers W1 subjected to the film forming process are transferred from the first processing spaces S21 to the second processing spaces S22 without passing through the vacuum transfer space S1, and the unprocessed wafers W3 are transferred to the first processing spaces S21. Then, the wafer holding unit 81 simultaneously delivers the wafers W1 subjected to the film forming process and the unprocessed wafers W3. When delivering the wafers W1 subjected to the film forming process, the lift pins (not illustrated) in the second processing spaces S22 are raised, and the wafers W1 subjected to the film forming process are delivered onto the lift pins. When the unprocessed wafers W3 are delivered, the lift pins (not illustrated) in the first processing spaces S21 are raised, and the unprocessed wafers W3 are delivered onto the lift pins.

### (D5: Pulling-Out of Wafer Holding Unit 81)

Thereafter, as illustrated in FIG. 12B, the entire wafer holding unit 81 is pulled out from the processing chamber 50, and the gate valves 52 and 54 are closed. At the same time, the lift pins (not illustrated) in the first processing spaces S21 and the lift pins (not illustrated) in the second processing spaces S22 are lowered, and the wafers W1 subjected to the film forming process are placed on the stages 55 in the second processing spaces S22 and the unprocessed wafers W3 are placed on the stages 55 in the first processing spaces S21. Thereafter, the annealing process for the wafers W1 subjected to the film forming process and the chemical vapor liquid film forming process for the unprocessed wafers W3 are initiated.

### (D6: Unloading of Wafers W2 Subjected to Annealing Process)

Subsequently, the wafer holding unit 80 is inserted into the load-lock chamber 12. Then, the wafers W2 subjected to the annealing process are delivered from the tip portions of the wafer holding unit 80 in the load-lock chamber 12.

### (D7: Receipt of Unprocessed Wafers W3)

Subsequently, the wafer holding unit 80 receives the unprocessed wafers W3 at the base portions thereof in the load-lock chamber 12.

Thereafter, the process is returned to the above-described operation D1, and operations D1 to D7 are repeated.

In the present embodiment as well, it is possible to transfer the wafers W1 subjected to the chemical vapor liquid film forming process to the second processing spaces S22 without passing through the vacuum transfer space S1. Therefore, the vacuum transfer space S1 is not adversely affected by the wafers W1 subjected to the chemical vapor liquid film forming process and to be subjected to the annealing process. In addition, it is possible to suppress the wafers W1 subjected to the chemical vapor liquid film forming process and to be subjected to the annealing process from being adversely affected by the atmosphere of the vacuum transfer space S1.

Furthermore, in the present embodiment, compared with the third embodiment, since it is possible to shorten the time from the completion of the chemical vapor liquid film forming process to the initiation of the annealing process, it is possible to improve throughput.

### <Modification>

In the above-described examples, in each of the processing chamber 50, the plurality of first processing spaces S21 and the plurality of second processing spaces S22 are arranged in a direction orthogonal to the wafer loading/unloading direction in the horizontal plane (the Y direction in the figures). The number of the first processing spaces S21 and the number of the second processing spaces formed in each processing chamber 50 are not limited to these examples and may each be one.

In the above-described examples, only the annealing process is performed in the second processing spaces S22, but a bevel etching process may be performed in parallel with the annealing process. As a result, it is possible to remove the above-mentioned intermediates formed on the bevel portions and the rear surfaces of wafers W in the chemical vapor liquid film forming process, thereby preventing the intermediates from adversely affecting the transfer of wafers W.

When the bevel etch process is performed in the second processing spaces S22, the interiors of the second processing spaces S22 are configured such that plasma is concentrated, for example, around the bevel portions of the wafers W.

In the above-described examples, the temperature control mechanism for the wafer W is the resistance heater embedded in the stage 55, but is not limited thereto. For example, the temperature control mechanism may be a coolant channel embedded in the stage 55 for dissipating heat from the wafer W, or may be a lamp heater or an LED heater provided above the stage 55.

In the above-described examples, the combination of the first process and the second process are the chemical vapor liquid film forming process and the annealing process, but is not limited thereto. For example, the first process may be a Ti film forming process, and the second process may be a TiN film forming process. The first process may be a cleaning process of removing a natural oxide film or an organic substance on the surface of the wafer W, and the second process may be a chemical vapor liquid film forming process or other film forming processes.

The embodiments disclosed herein should be considered to be exemplary in all respects and not restrictive. The embodiments described above may be omitted, replaced, or modified in various forms without departing from the scope and spirit of the appended claims.

### EXPLANATION OF REFERENCE NUMERALS

1, 1a: wafer processing apparatus, 40: vacuum transfer chamber, 50: processing chamber, 60: wafer transfer mechanism, 70: wafer holder, W: wafer

1. A substrate processing apparatus for processing a substrate, comprising:
a vacuum transfer chamber having a vacuum transfer space defined therein while being kept in a vacuum atmosphere, and including a substrate transfer mechanism provided in the vacuum transfer space and configured to collectively hold and transfer a plurality of substrates with a substrate holder; and
a processing chamber having a plurality of processing spaces defined therein while being kept in the vacuum atmosphere, and connected to the vacuum transfer chamber,
wherein the processing chamber includes a loading/unloading port provided on a side of the vacuum transfer chamber and configured to allow the vacuum transfer space and the plurality of processing spaces to communicate with each other,
wherein the plurality of processing spaces include a first processing space in which a first process is performed on the substrate loaded into the first processing space through the loading/unloading port, and a second processing space in which a second process is performed on the substrate subjected to the first process,
wherein the first processing space and the second processing space are arranged in a substrate loading/unloading direction in which the substrate is loaded and unloaded via the loading/unloading port by the substrate transfer mechanism, and
wherein the substrate holder of the substrate transfer mechanism has a length that extends over the first processing space and the second processing space.

2. The substrate processing apparatus of claim 1, wherein the substrate holder is configured to move in the wafer loading/unloading direction after receiving the substrate subjected to the first process inside the first processing space, so that the substrate is transferred to the second processing space without passing through the vacuum transfer space.

3. The substrate processing apparatus of claim 1, wherein a delivery of the substrate with respect to the substrate holder inside the first processing space and a delivery of the substrate with respect to the substrate holder inside the second processing space are performed at a same timing.

4. The substrate processing apparatus of claim 1, wherein the first processing space is located on a rear side of the vacuum transfer chamber, and the second processing space is located on a front side of the vacuum transfer chamber.

5. The substrate processing apparatus of claim 4, wherein the substrate holder is configured to hold a substrate subjected to the second process in addition to the substrate subjected to the first process, when transferring the substrate subjected to the first process from the first processing space to the second processing space.

6. The substrate processing apparatus of claim 5, wherein the substrate holder is configured to further receive the substrate subjected to the second process inside the second processing space at a timing of receiving the substrate subjected to the first process inside the first processing space.

7. The substrate processing apparatus of claim 4, wherein the substrate transfer mechanism is configured to hold and transfer only the substrate to be subjected to the first process with the substrate holder to the first processing space in a state in which the substrate subjected to the first process is located in the second processing space.

8. The substrate processing apparatus of claim 1, wherein the first processing space is located on a front side of the vacuum transfer chamber, and the second processing space is located on a rear side of the vacuum transfer chamber.

9. The substrate processing apparatus of claim 8, wherein the substrate transfer mechanism is configured to receive the substrate subjected to the first process inside the first processing space with the substrate holder which is holding a substrate to be subjected to the first process, and subsequently to move the substrate subjected to the first processing held by the substrate holder to the rear side to be transferred to the second processing space.

10. The substrate processing apparatus of claim 9, wherein the substrate holder is configured to deliver the substrate subjected to the first process inside the second processing space at a timing of delivering the substrate to be subjected to the first process inside the first processing space.

11. A substrate processing method in a substrate processing apparatus for processing a substrate,
wherein the substrate processing apparatus includes:
a vacuum transfer chamber having a vacuum transfer space defined therein while being kept in a vacuum atmosphere, and including a substrate transfer mechanism provided in the internal vacuum transfer space and configured to collectively hold and transfer a plurality of substrates with a substrate holder; and
a processing chamber having a plurality of processing spaces defined therein while being kept in the vacuum atmosphere, and connected to the vacuum transfer chamber,
wherein the processing chamber includes a loading/unloading port provided on a side of the vacuum transfer chamber and configured to allow the vacuum transfer space and the plurality of processing spaces to communicate with each other,
wherein the plurality of processing spaces include a first processing space in which a first process is performed on the substrate loaded thereinto through the loading/unloading port, and a second processing space in which a second process is performed on the substrate subjected to the first process, and
wherein the first processing space and the second processing space are arranged in a substrate loading/unloading direction in which the substrate is loaded and unloaded via the loading/unloading port by the substrate transfer mechanism,
the substrate transfer method comprising:
moving the substrate holder in the wafer loading/unloading direction after receiving the substrate subjected to the first process with the substrate holder inside the first processing space so that the substrate subjected to the first process is transferred to the second processing space without passing through the vacuum transfer space.

12. The substrate processing method of claim 11, further comprising:
performing a delivery of the substrate with respect to the substrate holder inside the first processing space and a delivery of the substrate with respect to the substrate holder inside the second processing space at a same timing.

13. The substrate processing method of claim 11, wherein, in the substrate processing apparatus, the first processing space is located on a rear side of the vacuum transfer chamber, and the second processing space is located on a front side of the vacuum transfer chamber.

14. The substrate processing method of claim 13, further comprising:
holding and transferring the substrate subjected to the first process with the substrate holder which holds the substrate subjected to the second process, from the first processing space to the second processing space.

15. The substrate processing method of claim 14, further comprising:
receiving, by the substrate holder, the substrate subjected to the second process inside the second processing space at a timing at which the substrate holder receives the substrate subjected to the first process inside the first processing space.

16. The substrate processing method of claim 13, further comprising:
holding and transferring only a substrate to be subjected to the first process with the substrate holder to the first processing space in a state in which the substrate subjected to the first process is located in the second processing space.

17. The substrate processing method of claim 11, wherein, in the substrate processing apparatus, the first processing space is located on a front side of the vacuum transfer chamber, and the second processing space is located on a rear side of the vacuum transfer chamber.

18. The substrate processing method of claim 17, further comprising:
receiving the substrate subjected to the first process inside the first processing space with the substrate holder which is holding a substrate to be subjected to the first process, and subsequently to move the substrate subjected to the first processing held by the substrate holder to the rear side to be transferred to the second processing space.

19. The substrate processing method of claim 18, further comprising:
delivering the substrate subjected to the first process inside the second processing space with the substrate holder at a timing of delivering the substrate to be subjected to the first process inside the first processing space; and
delivering the substrate subjected to the first process from the substrate holder in the second processing space at a timing at which the substrate holder transfers the substrate to be subjected to the first process from the substrate holder inside the first processing space.
